(19) United States
(12) Patent Application Publication
(10) Pub. No.: US 2011/0088744 A1
(43) Pub. Date: Apr. 21, 2011

(54) Photovoltaic Module Failure Detection Devices and Methods

(75) Inventors: Zhiyong Xia, Rockville, MD (US); Eric E. Daniels, Ijamsville, MD (US); Daniel W. Cunningham, Mount Airy, MD (US)

(73) Assignee: BP CORPORATION NORTH AMERICA INC., Warrenville, IL (US)

(21) Appl. No.: 12/908,953

(22) Filed: Oct. 21, 2010

Related U.S. Application Data
(60) Provisional application No. 61/253,648, filed on Oct. 21, 2009.

(51) Int. Cl. H01L 31/042; H01L 31/18; G01R 31/26

(52) U.S. Cl. 136/244; 29/890.033; 324/761.01

(57) ABSTRACT

Photovoltaic module failure detection devices and methods provide reliable, low cost, and effective solutions with visual indication of a temperature of diodes during installation, commissioning, operation, and/or maintenance. Indication of diode temperatures and/or detection of diode failures assures proper installation, improves output, expedites maintenance, increases safety, and/or raises reliability. A photovoltaic module for converting light into electricity includes one or more solar cells, and a transparent front sheet disposed over the one or more solar cells. The photovoltaic module includes a back sheet opposite the transparent front sheet, and one or more electrical circuits with one or more diodes connected to at least a portion of the one or more solar cells. The module includes one or more temperature indication devices in communication with at least a portion of the one or more diodes and disposed between the transparent front sheet and the back sheet.

This application claims the benefit of U.S. Provisional Application No. 61/253,648 filed Oct. 21, 2009, the entirety of which is expressly incorporated herein by reference.

### BACKGROUND

1. Field of the Invention

This invention relates to photovoltaic module failure detection devices and methods.

2. Discussion of Related Art

Photovoltaic devices seek to convert solar energy into electricity. There has been much effort and investment into improving photovoltaic devices and related components to improve efficiency, power output, reliability, and safety. To achieve these functions, photovoltaic devices are generally protected by incorporating one or more diodes into the electrical circuit of the photovoltaic device. Due to the electrical configuration in modern modules and the electrical limitations of the diodes, there has been an increased incidence of diode related failures in modern photovoltaic modules. Therefore, there remains a need and a desire for reliable, low cost, and effective devices and methods to detect failures of photovoltaic module diodes.

### SUMMARY

This invention relates to photovoltaic module diode failure detection devices and methods. This invention can provide reliable, low cost, and effective devices and methods to detect failures of photovoltaic module diodes, which in turn improves performance and reliability of photovoltaic modules. The methods and devices provide visual indication of a temperature of the diodes during installing, pre-commission checking, commissioning, operation, and/or maintenance. Indication of diode temperatures and/or detection of diode failures can assure proper installation, improve output, expedite maintenance, increase safety, raise reliability, and/or the like.

According to a first embodiment, this invention relates to a method of installing, pre-commission checking, commissioning, operating, and/or maintaining a photovoltaic array and/or system. The method includes the step of providing one or more photovoltaic modules. The one or more photovoltaic modules include one or more solar cells, one or more diodes electrically connected to the one or more solar cells, and one or more temperature indication devices in communication with at least a portion of the one or more diodes. The temperature indication devices reside within at least a portion of the one or more photovoltaic modules. The invention includes the step of detecting a failure of the one or more diodes with the one or more temperature indication devices.

According to a second embodiment, this invention relates to a photovoltaic module for converting light into electricity. The photovoltaic module includes one or more solar cells, and a transparent front sheet disposed over the one or more solar cells. The photovoltaic module includes a back sheet opposite the transparent front sheet, and one or more electrical circuits connected to at least a portion of the one or more solar cells and including one or more diodes. The photovoltaic module includes one or more temperature indication devices in communication with at least a portion of the one or more diodes. The photovoltaic module includes the one or more temperature indication devices disposed between the transparent front sheet and the back sheet.

According to a third embodiment, this invention includes an array of photovoltaic modules with the features and/or characteristics of this invention.

According to a fourth embodiment, this invention includes a method of fabricating a photovoltaic module. The method includes the step of providing one or more solar cells, and the step of electrically connecting one or more electrical circuits to the one or more solar cells. The method includes the step of contacting at least a portion of the one or more electrical circuits with one or more temperature indication devices, and the step of encapsulating the one or more solar cells, at least a portion of the one or more electrical circuits, and the one or more temperature indication devices between a transparent front sheet and a back sheet.

### BRIEF DESCRIPTION OF THE DRAWINGS

The above and other features and aspects of this invention are better understood from the following detailed description taken in view of the drawings wherein:

FIG. 1 shows a photovoltaic array, according to one embodiment;

FIG. 2 shows a photovoltaic module, according to one embodiment;

FIG. 3A shows an electrical circuit, according to one embodiment;

FIG. 3B shows an electrical circuit, according to one embodiment;

FIG. 4 shows a photovoltaic module, according to one embodiment;

FIG. 5 shows an active device, according to one embodiment;

FIG. 6 shows a passive device, according to one embodiment;

FIG. 7 shows a passive device, according to one embodiment; and

FIG. 8 shows a scale, according to one embodiment.

### DETAILED DESCRIPTION

According to one embodiment, the invention may include a method for monitoring a diode temperature in photovoltaic modules to provide early warning of faulty installation, visual indication of by-pass diode failure, and/or the like. Overheating and/or burning of diodes can lead to failures in photovoltaic modules, arrays, and/or systems. The overheating of diodes can be due to a number of factors including shading of cells, cracked cells, mismatched cells, wrong installation, poor workmanship, and/or the like. This invention may include visual indication of a system fault during installation, such as to assist during system commissioning. Installers can visually see potential system faults before they become damaging and/or catastrophic. System owners can have greater assurance that the systems have been properly commissioned upon transfer of title. A visual indication of bypass diode temperatures and/or their failures can also improve mean time to repair and/or improve system energy generation through visual identification of module performance without a need for electrical measurement and/or disassembly. This assures all internal module electronics can be working properly as deployed in the field. Furthermore, with the overheated modules properly identified and removed, reliability and/or overheating related safety issues of the module and/or system can be mitigated.

According to one embodiment, this invention may provide direct indication of properly performing diodes and photovoltaic modules deployed in the field, such as by monitoring an actual diode temperature while modules are generating power in the field. This invention can provide at least three functions: 1) prevent system or module damage from improper installation; 2) provide evidence and/or documentation that certain diodes have experienced temperatures higher than a rated temperature; and/or 3) provide visual results to identify failed diodes and/or suboptimal performing modules. The invention can provide guidance for proper actions on problematic modules or cell strings.

Given all the benefits above, this invention can assure proper installation and commissioning of solar products. The solar products can operate with increased reliability and output. This invention can also assist with system operating and maintenance protocols by providing visual indication of failed diodes and/or photovoltaic modules.

According to one embodiment, this invention may include in-situ and/or real time temperature monitoring of the diode in photovoltaic modules. As a result, by simply looking at a photovoltaic module from a front side, one can see which module has seen high current and may need to be replaced or repaired. This feature and/or characteristic can make products safer and more reliable than those without temperature indication devices.

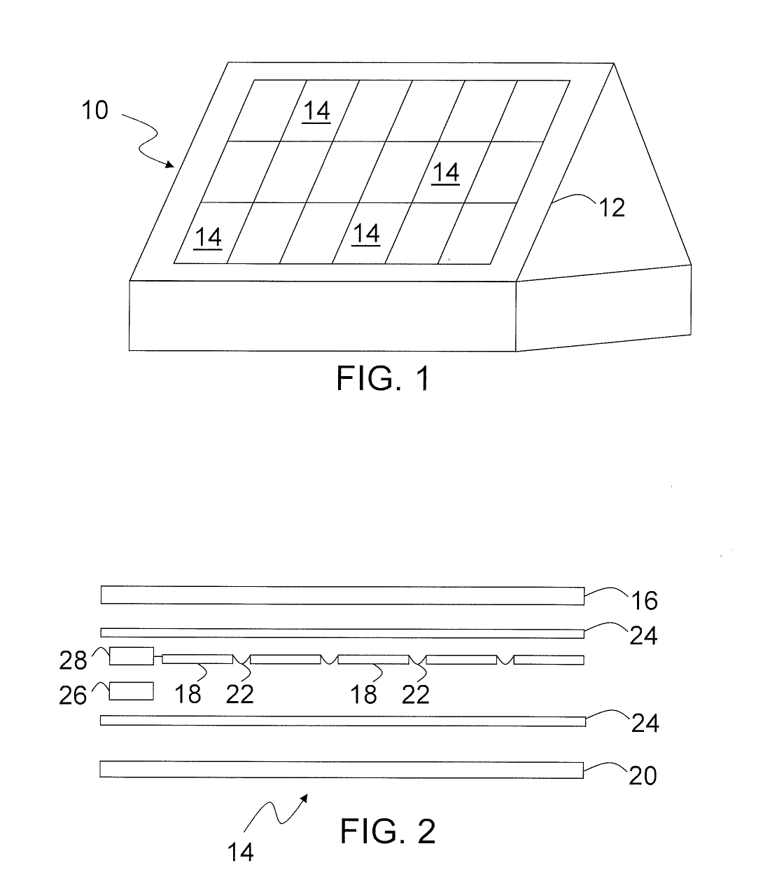

FIG. 1 shows a photovoltaic array 10, according to one embodiment. The photovoltaic array 10 can mount to a support structure 12 and include photovoltaic modules 14.

FIG. 2 shows a partial exploded schematic view of a photovoltaic module 14, according to one embodiment. The photovoltaic module 14 includes a transparent front sheet 16 and a back sheet 20 with solar cells 18 disposed between the transparent front sheet 16 and the back sheet 20. Wiring 22 connects the solar cells 18. One or more layers of encapsulant 24 bonds components of the photovoltaic module 14 together. The photovoltaic module 14 includes a temperature indicating device 26 and a diode board or a diode 28 disposed within the photovoltaic module 14. The temperature indicating device 26 thermally contacts and/or communicates with at least a portion of the diode 28.

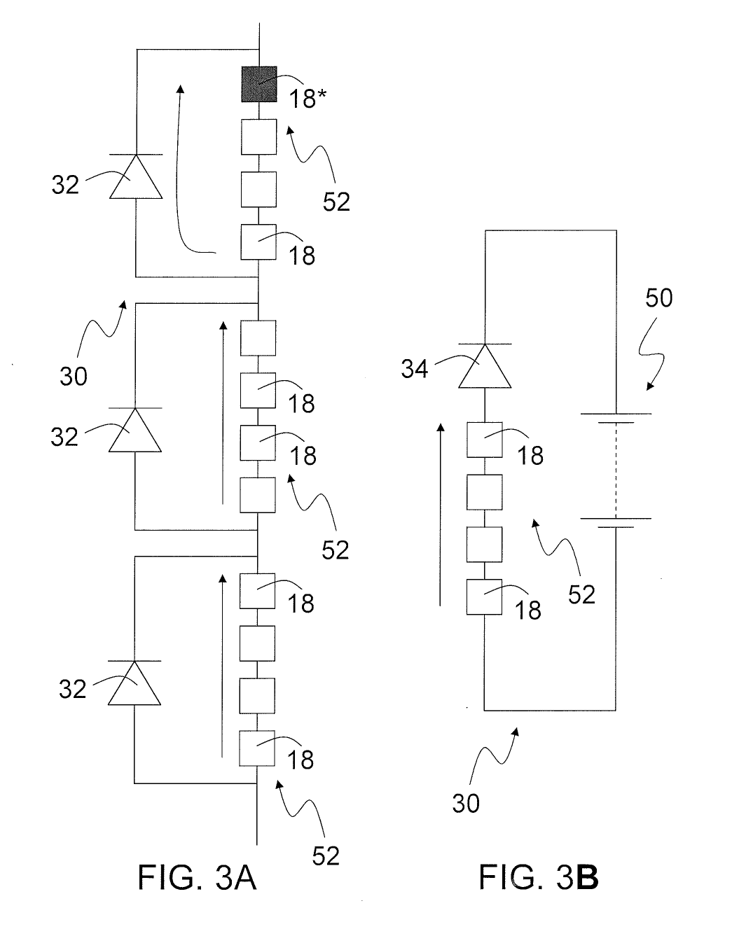

FIG. 3A shows a portion of an electrical circuit 30, according to one embodiment. The electrical circuit 30 includes bypass diodes 32 connected in parallel with a cell string 52 or a portion of a photovoltaic module 14 (not shown) which include solar cells 18. The arrows indicate electrical current flow, such as through the solar cells 18 when all of the solar cells 18 function properly and through the bypass diode 32 when one solar cell 18* (shown in black) does not function properly.

FIG. 3B shows a portion of a different electrical circuit 30, according to one embodiment. The electrical circuit 30 includes a blocking diode 34 connected in series with a cell string 52 or a portion of a photovoltaic module 14 (not shown) which includes solar cells 18. The arrow indicates normal electrical current flow, such as forward through the solar cells 18 and a forward direction of the blocking diode 34 while charging a rechargeable battery 50. Embodiments of the electrical circuit 30 with both bypass diodes 32 and blocking diodes 34 are within the scope of this invention (not shown).

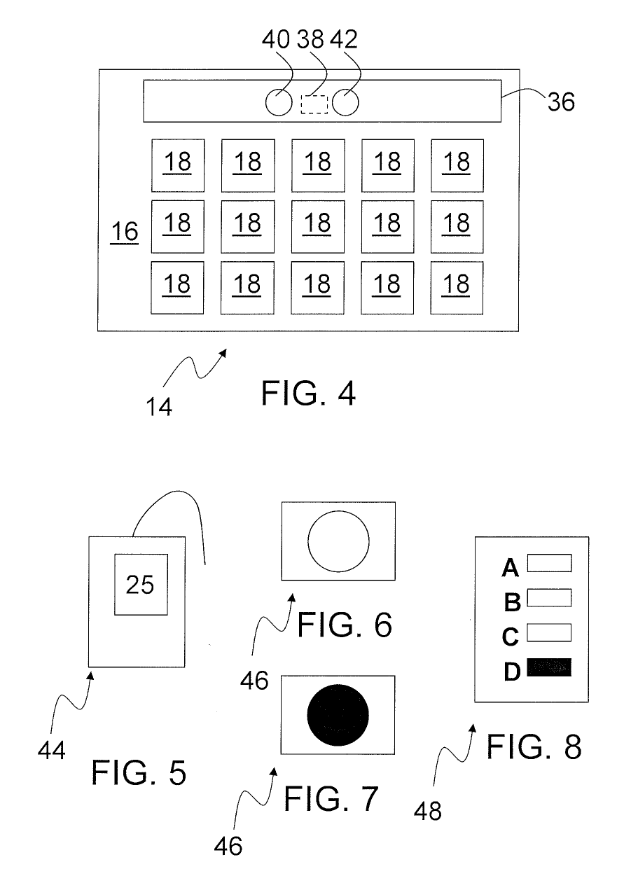

FIG. 4 shows a photovoltaic module 14, according to one embodiment. The photovoltaic module 14 includes a transparent front sheet 16, solar cells 18, an electrically conducting board or a printed circuit board 36, a surface mount Schottky diode 38, a reversible temperature indication device 40, and a non-reversible temperature indication device 42. The surface mount Schottky diode 38 mounts to a bottom side of the printed circuit board 36, such as facing (oriented inward) the solar cells 18 and shown by a dashed line. The reversible temperature indication device 40, and the non-reversible temperature indication device 42 have thermal communication with the surface mount Schottky diode 38. The reversible temperature indication device 40, and the non-reversible temperature indication device 42 mount to a top (opposite or outward oriented) side of the printed circuit board 36. The transparent front sheet 16 disposes over the solar cells 18, the electrically conducting board 36, the surface mount Schottky diode 38, the reversible temperature indication device 40, and the non-reversible temperature indication device 42.

FIG. 5 shows an active device 44, according to one embodiment. The active temperature indication device 44 may include a thermocouple and a thermocouple reader.

FIG. 6 shows a passive device 46, according to one embodiment. The passive temperature indication device 46 can be a temperate dot or temperature label with a circle. The passive temperature indication device 46 can be a reversible temperature indication device and/or a non-reversible temperature indication device. The passive temperature indication device 46 of FIG. 6 shows a state below a threshold temperature. The passive temperature indication device 46 can use shapes, color, printed symbols, letters, words, and/or the like.

FIG. 7 shows the passive temperature indication device 46 of FIG. 6 except in a state at and/or exceeding a threshold temperate as evidenced by a color change of the circle.

FIG. 8 shows a scale 48, according to one embodiment with threshold temperature ranges A, B, C, and D. Range D has changed color to indicate reaching a threshold temperature corresponding to range D. The scale can be a temperature label.

According to one embodiment, the invention may include a method of installing, commissioning, operating, maintaining, and/or the like a photovoltaic array. The method may include a step of providing one or more photovoltaic modules. The one or more photovoltaic modules may include one or more solar cells, one or more diodes electrically connected to the one or more solar cells, and one or more temperature indication devices in communication with at least a portion of the one or more diodes. The one or more temperature indication devices can be located within at least a portion of the one or more photovoltaic modules. The invention may include the step of detecting a failure of the one or more diodes with the one or more temperature indication devices.

Method broadly refers to a procedure and/or process for attaining an object and/or an outcome, such as a series and/or a sequence of steps and/or instructions, and/or the like.

Installing broadly refers to put in place, mount, anchor, affix, fix, locate, dispose, set for service, set for use, and/or the like. Installing may include mounting one or more solar modules to a suitable support surface, such as a roof, a structure, the Earth, a satellite, and/or the like. Installing may include any suitable fastener and/or attaching device, such as nails, screws, bolts, nuts, mechanical fasteners, adhesive fasteners, chemical fasteners, and/or the like. Installing may be completed by any suitable person and/or party, such as a photovoltaic module supplier, an installing contractor, an owner, an operating contractor, a technician, a robot, and/or the like.

Commissioning broadly refers to put into and/or enable for service and/or use. Commissioning may include one or more steps and/or tests to verify installation, such as wiring checks and/or power output level verifications. Commissioning may include initial system benchmarks, safety checks, and/or the like. Commissioning may be completed by any suitable person and/or party, such as a photovoltaic module supplier, an installing contractor, an owner, an operating contractor, a technician, a robot, and/or the like.

Operating broadly refers to performing a function, producing an affect, carrying out one or more steps, and/or the like. Operating may include routine actions during generation of electricity with a photovoltaic module, such as cleaning, adjusting, monitoring, performing preventative maintenance, and/or the like. Operating may be completed by any suitable person and/or party, such as a photovoltaic module supplier, an installing contractor, an owner, an operating contractor, a technician, a robot, and/or the like.

Maintaining broadly refers to sustaining, keeping in an existing and/or operating state, to repair, to replace, and/or the like. Maintaining may include repair and/or replacement of components of a photovoltaic module and/or a photovoltaic array, such as solar cells, wiring, structural members, and/or the like. Maintaining may be completed by any suitable person and/or party, such as a photovoltaic module supplier, an installing contractor, an owner, an operating contractor, a technician, a robot, and/or the like.

Photovoltaic broadly refers to generation and/or production of electrical voltage and/or electrical current when radiant energy falls on and/or contacts a substance, and/or the like. Radiant energy broadly refers to at least a portion of the electromagnetic spectrum, such as infrared light, visible light, ultraviolet light, and/or the like. Photovoltaic devices may use a boundary between dissimilar substances, such as a p-n junction formed between a p-type doped region and an n-type doped region of a silicon substrate and/or wafer.

Solar broadly refers to relating to and/or derived from the Sun, such as may include uses to produce heat, electricity, power, and/or the like.

Photovoltaic array and/or solar array broadly refers to a collection and/or a placement of one or more photovoltaic modules, and/or the like. Photovoltaic arrays may include any suitable configuration of photovoltaic modules wired and/or connected in series and/or parallel configurations and/or arrangements. Photovoltaic arrays may include any suitable number of photovoltaic modules, such as one or more, at least about 10, at least about 100, at least about 1,000, and/or the like. Photovoltaic arrays may occupy and/or consume any suitable amount of area and/or space, such as at least about 1 meter squared, at least about 10 meters squared, at least about 100 meters squared, at least about 1,000 meters squared, and/or the like. Photovoltaic arrays can connect to one or more electrical loads, such as appliances, motors, rechargeable batteries, an electrical distribution grid, and/or the like.

Embodiments with multiples and/or combinations of photovoltaic arrays are within the scope of this invention. Embodiments of photovoltaic arrays with solar collectors, solar mirrors, solar concentrators, and/or the like are within the scope of this invention.

Providing broadly refers to supplying and/or making available, making ready, and/or the like.

Photovoltaic module and/or solar module broadly refers any suitable device and/or apparatus for converting and/or transforming at least a portion of the electromagnetic spectrum into electricity, and/or the like. Photovoltaic modules may include solar panels, frames, support structures, electrical circuits, related wiring, junction boxes, current inverters, electrical transformers, other related equipment, and/or the like.

Photovoltaic modules may include one or more solar cells in a suitable electrical combination and/or arrangement, such as a series circuit and/or a parallel circuit. The photovoltaic module may include any suitable number of solar cells, such as at least about 1, at least about 10, between about 10 and about 200, between about 50 and about 100, about 72, at least about 50, and/or the like. The solar cells may include any suitable size and/or shape, such as between about 10 millimeters squared to about 100,000 millimeters squared, about 15,625 millimeters squared, about 24,336 millimeters squared, and/or the like.

Photovoltaic cells and/or solar cells broadly refer to a suitable device or apparatus to convert and/or transform photons into electricity. Solar cells may include any suitable material, such as Czochralski silicon, float zone silicon, monocrystalline silicon, near monocrystalline silicon, microcrystalline silicon, multicrystalline silicon, geometric multicrystalline silicon, amorphous silicon, metallurgical grade silicon, cast silicon, sheet silicon, ribbon silicon, cadmium sulfide, cadmium telluride, copper indium selenide, copper indium gallium selenide, germanium, gallium arsenide, organic materials, polymer materials, other photoelectric materials, and/or the like. Solar cells may include thick structures and/or thin structures.

Photovoltaic modules may include a transparent front sheet, such as tempered glass, float glass, low iron glass, polycarbonate, poly (methyl methacrylate), polystyrene, fluoropolymer, other suitable polymers, and/or the like. The transparent front sheet desirably passes and/or transmits at least about 50 percent of incident light, at least about 75 percent of incident light, at least about 90 percent of incident light, and/or the like. The transparent front sheet may include a suitable antireflective coating, such as to reduce loss of light from an incident surface. Suitable antireflective coatings may include porous silicon oxides, a coating material with a refractive index between air and the transparent front sheet, and/or the like. The transparent front sheet may be rigid, semi-rigid, flexible, semi-flexible, and/or the like, such as depending upon a type of solar cells used in the photovoltaic module. The transparent front sheet can be disposed and/or placed over and/or in contact with a light receiving side of the solar cells.

Photovoltaic modules may include a back sheet, such as including and/or formed from polyester, fluoropolymer, aluminum, glass, multi-layered composite, other suitable polymer material, other suitable metal material, a rigid material, and/or the like. Desirably, the back sheet includes good moisture resistance properties and/or good electrical insulation properties (dielectric). Back sheets may include a filler material, such as glass fiber, minerals, organic substances, and/or the like. Filler materials may improve heat (thermal) properties, electrical properties, optical properties, physical properties, mechanical properties, and/or the like with respect to at least a portion of the photovoltaic module. The back sheet may include one or more adhesion promoters and/or coupling agents, such as to improve bonding between different layers during device fabrication. Adhesion promoters may include organic silane compounds, epoxy compounds, and/or the like. The back sheet can be disposed and/or placed under and/or in contact opposite (on the other side of) the light receiving side of the solar cells and/or the transparent front sheet.

Use of bifacial (two sided) solar cells are within the scope of this invention.

Photovoltaic modules may include an encapsulant to laminate, bond, hold, adhere, glue, encase, cover, and/or the like at least a portion of one or more components of the photovoltaic module. The encapsulant may include any suitable compound and/or substance, such as ethylene vinyl acetate, polysilicone, polyvinyl butyral, and/or the like. Encapasulants may include thermoplastic materials, thermoplastic materials with crosslinking agents, thermoset materials, and/or the like. Encapsulants may include a filler material, such as glass fiber, minerals, organic substances, inorganic substances, and/or the like. Filler materials may improve heat (thermal) properties, electrical properties, optical properties, physical properties, mechanical properties, and/or the like with respect to at least a portion of the photovoltaic module. The encapsulant may include one or more adhesion promoters and/or coupling agents such as to improve bonding. Adhesion promoters may include organic silane compounds, epoxy compounds, and/or the like.

According to one embodiment, a first layer of encapsulant can be placed and/or located between the transparent front sheet and the solar cells. A second layer of encapsulant can be placed and/or located between the solar cells and the back sheet. A laminate and/or sandwich of the materials can then be heated typically under vacuum to melt and/or cure at least a portion of the first layer of encapsulant and/or the second layer of encapsulant, such as to fuse the laminate and/or surround or cover at least a portion of the components. Embodiments lacking either the first layer of encapsulant or the second layer of encapsulant are within the scope of this invention. The first layer of encapsulant may include any suitable properties, such as good optical properties like a refractive index similar to the transparent front sheet. The second layer of encapsulant may include any suitable properties, such as increased cut resistance from addition of a glass mat and/or the like.

The photovoltaic module may include one or more electrical circuits. Electric or electrical broadly refers to and/or relates to electricity, such as a flow and/or a potential flow of electrons from and/or between two or more points and/or locations. Circuit broadly refers to a path for electricity and/or an assembly of electrical elements and/or components.

The photovoltaic module may include one or more power circuits, such as for transmitting and/or delivering electricity produced within at least a portion of the photovoltaic module. The photovoltaic module may include one or more control circuits, such as for operating and/or changing a state of at least a portion of the photovoltaic module and/or related equipment. The photovoltaic module may include one or more monitoring or status circuits, such as to confirm an operation and/or health of at least a portion of the photovoltaic module.

Diode broadly refers to an electrical apparatus and/or device with unidirectional electric current flow properties, such as may include rectifying capabilities. Diodes can operate in any suitable manner, such as to allow an electric current in one direction (forward biased condition) and to block electric current in an opposite direction (reverse biased condition). Diodes can operate analogously and/or like an electronic version of a check valve (fluid flow). Diodes may include any suitable configuration, such as surface mount diodes, and/or the like. Diodes may include any suitable type and/or kind, such as solid state diodes, Schottky diodes, and/or the like. Diodes can have a rated operating temperature. Without being bound by theory, exceeding the rated operating temperature for a short and/or sustained duration and/or time can result in damage and/or failure of the diode and may further a failure of the photovoltaic module circuit. Failed diodes can operate and/or act like an open circuit, such as preventing current flow through the diode even in a forward biased direction.

Diodes can be used for any suitable purpose in a photovoltaic circuit, module, and/or array, such as bypass diodes, blocking diodes, shunting diodes, and/or the like.

Bypass diodes broadly refer to diodes connected and/or wired in an at least generally parallel configuration with at least a portion of a photovoltaic cell string (one or more cells) and/or a photovoltaic module, such as to allow current to flow around at least a portion of the photovoltaic cell string. Bypass diodes can be activated or have current flow through the bypass diodes when there are damaged solar cells, shaded solar cells, mismatched cells, and/or the like. Embodiments with multiple bypass diodes for a photovoltaic module are within the scope of this invention, such as diodes corresponding to groups and/or strings of one or more solar cells.

Blocking diodes broadly refer to diodes connected and/or wired in an at least generally series configuration with at least a portion of one or more photovoltaic cell strings (one or more cells) and/or photovoltaic modules, such as to prevent current from backing up and or flowing into at least a portion of the photovoltaic module. In embodiments of the photovoltaic modules connected to rechargeable batteries, blocking diodes can prevent the draining of the batteries due to reverse current flow, when the modules are not generating enough power, and/or the like. The blocking diode can provide isolation, such as to stop and/or prevent electrical current reversal during night conditions without light and/or the like.

Without being bound by theory, reverse electrical current flow into a solar cell can cause and/or form hot spots, such as by dissipating energy into heat. Hot spots can cause and/or raise several issues, such as to reduce operating efficiency, lower electrical output, decrease reliability, form safety issues, and/or the like. Diodes in a circuit of the photovoltaic module and/or device can reduce and/or prevent the above issues. Failure and/or fault of the diodes can result in hot spots and the related issues.

Temperature broadly refers to a measure and/or an amount of an internal energy (heat) of an object and/or thing, such as an indication of hotness and/or coldness, and/or the like. Temperature can be measured by any suitable scale, such as Celsius, Fahrenheit, Kelvin, Rankine, and/or the like.

Indicate broadly refers to point to, to point out, to state, to qualify, to quantify, and/or the like.

Temperature indication device broadly refers to any suitable object and/or apparatus suitable to measure and/or provide indicia of a temperature of at least a portion of an object, device, and/or thing, and/or the like. Temperature indication devices may include active devices, passive device, and/or the like. Temperature indication devices can have any suitable temperature range, operating range and/or temperature span, such as between about −25 degrees Celsius to about 1,000 degrees Celsius, between about 0 degrees Celsius to about 500 degrees Celsius, between about 100 degrees Celsius to about 200 degrees Celsius, about 150 degrees Celsius, and/or the like. Temperature indication devices may include reversible devices, non-reversible devices, and/or the like. Temperature indication devices may be graduated and/or calibrated to provide degrees and/or intervals of temperature, such as with a scale.

Active devices broadly refer to equipment and/or apparatus that use and/or consume at least some amount and/or quantity of power from an external source, such as electrical energy and/or the like. Sources of power for active devices may include electrochemical batteries, electrical current supplies, solar cells, and/or the like. Active devices may include thermocouples, resistance temperature detectors, thermistors, temperature transmitters, and/or the like. Active devices can be wired, wireless, self contained, and/or the like. Active devices can send and/or transmit a suitable signal, such as an electrical signal, a radio frequency signal, an audible signal, a visual signal, and/or the like. Active devices can be analog and/or digital. According to one embodiment, the active device may include an active radio frequency identification (RFID) sensor and/or device.

Active and/or passive devices utilizing alternative energy capture and/or recovery techniques (power scavenging) are within the scope of this invention, such as capturing and/or converting solar energy, kinetic energy, thermal energy, vibrational energy, and/or the like.

Passive devices broadly refer to equipment and/or apparatus that do not use and/or consume at least some amount and/or quantity of power from an external source, such as a self-contained system. Passive devices may include thermometers, temperature sensitive materials, and/or the like. Thermometers can operate by any suitable principle, such as a density and/or volume change with temperate for a liquid, a thermal expansion for a solid (bimetallic), a color change for liquid crystalline materials, and/or the like. Temperature sensitive materials may include a temperature indication label, a temperature indication tape, a temperature indication dot, a temperature sensitive paint, a temperature melting material, a temperature softening material, a temperature activated cement, a temperature activated lacquer, a temperature activated crayon, and/or the like. Generally, the passive devices can indicate a temperature by one or more changes in color, shape and/or the like. According to one embodiment, the passive device includes a passive RFID sensor and/or device.

Reversible devices broadly refer to devices and/or equipment that can provide indication upon reaching and/or exceeding a threshold and/or trigger value and/or limit and then no longer provide indication once lowered below the threshold and/or trigger value and/or limit. For example, a reversible temperature dot may change from a light color to a dark color upon reaching and/or heating up to about 150 degrees Celsius. The reversible temperature dot can then change from the dark color to the light color upon lowering and/or cooling to below about 150 degrees Celsius. Reversible devices can be useful for repeatedly providing an indication of a current state of and/or an instantaneous operation of a portion of a photovoltaic module, such as a diode.

Non-reversible devices broadly refer to devices and/or equipment that can provide indication upon reaching and/or exceeding a threshold and/or trigger value and/or limit and then continue to provide indication even if lowered below the threshold and/or trigger value and/or limit. For example, a non-reversible temperature dot may change from a light color to a dark color upon reaching and/or heating up to about 150 degrees Celsius. The non-reversible temperature dot can then remain the dark color upon lowering and/or cooling to below about 150 degrees Celsius. Non-reversible devices can be useful for providing an indication of a historic state of and/or a prior operation of a portion of a photovoltaic module, such as a diode. The non-reversible device also can provide a current state if observed at a moment of change.

Graduated temperature indication devices may include any suitable number of temperatures and/or ranges, such as at least about 1, at least about 2, at least about 4, at least about 5, at least about 10, and/or the like. The ranges may include any suitable temperature span and/or set of values, such as about 1 degree Celsius, about 5 degrees Celsius, about 10 degrees Celsius, about 50 degrees Celsius, between about 5 degrees Celsius and about 25 degrees Celsius, and/or the like. Embodiments with varying and/or changing temperature ranges (unequal sizes) are within the scope of this invention, such as smaller rangers closer to a maximum operating temperature.

The temperature indication devices can be located and/or disposed at any suitable location and/or position with respect to the photovoltaic module, such as contained and/or laminated within a portion of the photovoltaic module. Within the photovoltaic module may include between at least a potion of the transparent front sheet and the back sheet, for example.

In communication broadly refers to an ability to exchange and/or transmit something, some characteristic, and/or some property, and/or the like. Communication may include any suitable form, such as thermal communication, physical communication (proximate contact, direct contact, and/or intimate contact), fluid communication, electrical communication, and/or the like.

Detecting broadly refers to discovering, determining, measuring, and/or the like. According to one embodiment, the step of detecting occurs visually (with eyes) by looking at and/or examining at least a portion of the one or more temperature indication devices. The detecting may exclude a use of additional readers, sensors, probes, detectors, recorders, loggers, and/or the like. In the alternative, the detecting may include the use of one or more of additional readers, sensors, probes, detectors, recorders, loggers, and/or the like. The reader may include a RFID reader and/or the like. Detecting may be through a portion of the photovoltaic module, such as the transparent front sheet, and/or the like.

Failure broadly refers to an inability or lack of performance of an expected action, outcome, operation, and/or the like. Failures may include a falling short, a deficiency to some degree, a total collapse, and/or the like. Without being bound by theory, failure of a diode may occur due to voltage transients (spikes), over current flows, temperature variances at or above a maximum junction temperature, and/or the like. Failed diodes can exhibit high current flow (short circuit) and/or no current flow (open circuit), such as depending on a failure mode and/or type. Overheated diodes can generally exhibit and/or act like open circuits, such as preventing current flow through the diode.

Without being bound by theory, the diodes in the photovoltaic module and/or array can fail for any number of causes and/or reasons, such as due to reverse current flow, improper electrical connection, reversed polarity, cracked (broken) solar cells, mismatched solar cells, full shading of one or more solar cells, partial shading of one or more solar cells, improper fusing within the photovoltaic module, improper grounding of the photovoltaic module, improper fusing outside the photovoltaic module, excessive environmental temperature (fire), and/or the like. The diodes can fail during fabrication, installation, commissioning, operation, maintenance, and/or the like.

According to one embodiment, the one or more diodes may include bypass diodes, blocking diodes, and/or the like. The step of detecting may include monitoring a passive device, an active device, and/or the like within the one or more photovoltaic modules or an array to assure proper installation, commissioning, operation, maintenance, reliability, safety, and/or the like. Detecting may include a visual observation of a temperature indication device with and/or without an additional device, such as a RFID reader, and/or the like.

Reliability broadly refers to consistent, dependable, regular results and/or operations. The photovoltaic modules can have any suitable mean time between failures, mean time to repair and/or the like, such as at least about 1,000 hours, at least about 5,000 hours, at least about 10,000 hours, and/or the like.

Safety broadly refers to avoiding loss, harm, hurt, injury, and/or the like. Safety can relate to personnel and/or property. Without being bound by theory, hot spots caused by failed diodes can pose an increased risk to personnel and/or property.

According to one embodiment, the method may include the step of correcting or repairing one or more of the one or more photovoltaic modules upon detecting a failure of the one or more diodes, or the step of replacing one or more of the one or more photovoltaic modules upon detecting a failure of the one or more diodes.

Correcting broadly refers to making right, fixing an error, reducing a fault, and/or the like. Correcting actions may include changing polarity of a photovoltaic module, providing proper fusing, and/or the like.

Repairing broadly refers to restoring, remedying, putting together something that is broke or not functioning, and/or the like. Repairing may include replacing one or more components of the photovoltaic module or array, such as a power cable, and/or the like.

Replacing broadly refers to put something in place of another, to substitute, and/or the like. Replacing may include swapping out at least a portion of a photovoltaic module for a different or new one.

According to one embodiment, a technician, an installer, a suitable person, a machine, and/or the like performs a check and/or inspection of an array of the photovoltaic modules by visually and/or optically inspecting the one or more temperature indication devices while traversing and/or moving along at least a portion of the array, such as during installation and/or commissioning, after installation and/or commissioning, and/or the like.

Traversing broadly refers to moving along and/or across, such as by walking, using a vehicle, and/or the like.

Checking and/or inspecting may include data recoding and/or logging functions and/or capabilities, such as using a pen and paper, an electronic device, and/or the like. Use of RFID tags, bar codes, global positioning system (GPS) coordinates, and/or other identification devices and/or systems for photovoltaic module and/or array identification and/or determination are within the scope of this invention.

According to one embodiment, the method may include where the step of visually checking includes easily observing a front portion, a side portion, a back portion, and/or the like of the photovoltaic module without physically opening a part and/or a portion of a photovoltaic module, such as a cover, a lid, a back sheet, a front sheet cover, a junction box, and/or the like.

Easily broadly refers to without difficulty and/or impediment. Easily may include at any suitable distance, such as less than about 0.2 meters, at least about 0.5 meters, about 1 meter, at least about 1 meter, at least about 3 meters, at least about 5 meters, at least about 10 meters, and/or the like.

Observing broadly refers to inspecting, watching carefully, noting, and/or the like. Observing can also include logging and/or recoding a state and/or a condition of the temperature indication device, such as above and/or below a threshold temperature.

According to one embodiment, the detecting of a failure of the one or more diodes may include monitoring an approach to a temperature rating of the one or more diodes, or monitoring a rise to or above a temperature rating of the one or more diodes.

Monitoring broadly refers to watching, keeping track of, checking, and/or the like.

Temperature rating broadly refers to a maximum allowable temperature and/or other suitable number and/or range for a device and/or an apparatus, such as between about 100 degrees Celsius to about 300 degrees Celsius, between about 125 degrees Celsius to about 300 degrees Celsius, between about 125 degrees Celsius to about 200 degrees Celsius, about 150 degrees Celsius, about 175 degrees Celsius, and/or the like. Maximum allowable temperature can vary based on diode type, design, size, materials, and/or the like.

Approach broadly refers to drawing near to, getting close to, and/or the like. An approach may include any suitable temperature and/or range away from a set value, such as about 50 degrees Celsius, about 25 degrees Celsius, about 10 degrees Celsius, about 5 degrees Celsius, about 1 degree Celsius, and/or the like.

Without being bound by theory, catching and/or stopping a diode from reaching and/or exceeding a temperature rating may actively and/or proactively prevent and/or reduce damage and/or harm to persons and/or property, such as a portion of the photovoltaic module and/or photovoltaic array including the solar cells and/or the diodes. Preventing diode overheating may increase and/or lengthen reliability and/or safety of the photovoltaic module or array. Suitable actions to prevent diode overheating may include electrically isolating a photovoltaic module (disconnecting), providing cooling (air, water, and/or the like), identifying and repairing a failed component, and/or the like.

According to one embodiment, the method may include the step of mounting one or more photovoltaic modules to a support structure, and the step of electrically connecting the one or more photovoltaic modules.

Mounting broadly refers to attaching, affixing, and/or placing, such as with suitable fasteners and/or anchors. Suitable fasteners and/or anchors may include nails, nuts, bolts, screws, rivets, mechanical fasteners, adhesives, sealants, chemical fasteners, and/or the like.

Support structure broadly refers to any suitable location and/or position, such as on a roof, on a side of a building, on a frame, on the ground, and/or the like. Support structures may include residential buildings, agricultural buildings, commercial buildings, industrial buildings, and/or the like.

Electrically connected broadly refers to any suitable step and/or action to allow a flow of electricity between two or more locations and/or devices, such as by wiring, making terminal connections, soldering, welding, twisting, bolting, providing continuity, and/or the like.

According to one embodiment, the invention may include a photovoltaic module for converting light into electricity. The module may include one or more solar cells, and a transparent front sheet disposed over the one or more solar cells. The module may include a back sheet opposite and/or under the transparent front sheet, and one or more electrical circuits connected to at least a portion of the one or more solar cells. The one or more electrical circuits may include one or more diodes. The module may include one or more temperature indication devices in communication with at least a portion of the one or more diodes. The one or more temperature indication devices can be disposed between the transparent front sheet and the back sheet.

The apparatus of this specification may include any and/or all of the features and/or characteristics of the methods described within this specification and vice versa.

Between broadly refers to an intermediate space and/or interval. Desirably, but not necessarily items disposed between others may have a suitable form of communication, such as physical (touching or contacting), thermal, electrical, and/or the like.

According to one embodiment, the module includes one or more electrically conducting boards disposed between the transparent front sheet and the back sheet. At least a portion of the one or more electrical circuits can be mounted to the one or more electrically conducting boards.

The electrically conducting boards and/or materials may include printed circuit boards and/or the like. The diodes can mount on and/or to the electrically conducing boards. According to one embodiment, the diodes can be pre-mounted to the printed circuit board. Desirably, but not necessarily, the electrically conducting boards may include heat sinking and or cooling capabilities for the diodes and/or electrical circuits. Without being bound by theory, encapsulating the electrically conducting boards directly into the photovoltaic module can improve reliability, operability, and/or safety versus modules placing diodes in junction boxes on a backside of the module. Modules with electrically conducting boards laminated between the transparent front sheet and the back sheet can be purchased from BP Solar, Frederick, Md., U.S.A. under the trade name Integrabus™.

Modules with the temperature indicating device laminated between the transparent front sheet and the back sheet (internal or inside) can be more reliable than placing a temperature indication device on an exterior (external or outside) of a photovoltaic module, such as where weather (precipitation) and/or like may cause the temperature indication device to peel off, fade in color, and/or fail, for example.

Embodiments of the photovoltaic module with combinations of reversible devices and non-reversible devices can provide both instantaneous status and historical status information. Reversible devices and non-reversible devices can have a same threshold temperature and/or different threshold temperatures, such as a difference of at least about 5 degrees Celsius, at least about 10 degrees Celsius, at least about 20 degrees Celsius, at least about 30 degrees Celsius and/or the like. The reversible temperature indicating device may have the lower threshold temperature. In the alternative, the non-reversible temperature indicating device may have the lower threshold value. Other combinations of temperature indicating devices are within the scope of this invention.

The temperature indication devices may mount with respect to the electrically conducing boards at any suitable location, such as a same side and/or an opposite side of the one or more diodes. The electrically conducting boards may have any suitable size and/or shape, such as a generally elongate form with a width of between about 1 centimeter to about 10 centimeters and a length of between about 10 centimeters and about 3 meters, and/or the like.

Without being bound by theory, placing the temperature indicating device on the electrically conducting boards rather than directly on a diode can cause a temperature offset and/or lag with regard to reading a temperature of the diode. Corrections and/or allowances for the offset and/or lag can be provided, such as by providing allowances for heat transfer behavior (convection, conduction, and/or radiation) and material properties (thermal conductivity, thermal emissivity, and/or the like).

According to one embodiment of the photovoltaic module, the one or more diodes mount to one or more electrically conducting boards laminated between the transparent front sheet and the back sheet with the one or more diodes facing the one or more solar cells, and the one or more temperature indication devices mount to the circuit board on a same side and/or an opposite side as the one or more diodes.

According to one embodiment of the photovoltaic module, the one or more temperature indication devices provide visual indication related to a temperature of at least a portion of the one or more electrical circuits, such as bypass diodes, blocking diodes, other electrical components, and/or the like.

According to one embodiment of the photovoltaic module, the one or more diodes may include bypass diodes, blocking diodes, and/or the like.

According to one embodiment of the photovoltaic module, the one or more diodes may include surface mount technology Schottky diodes integrally laminated into a portion of the photovoltaic module.

According to one embodiment of the photovoltaic module, the one or more temperature indication devices may include reversible temperature indication devices, non-reversible temperature indication devices, active temperature indication devices, passive temperature indication devices, and/or the like.

According to one embodiment of the photovoltaic module, the one or more temperature indication devices may include a scale to illustrate a temperature range, a color change to indicate a certain threshold temperature, a shape change to show certain threshold temperature has been reached, and/or the like.

Scale broadly refers to a graduated series of measured intervals and/or the like. Scales can have any suitable numbers of intervals, such as at least about 1, between about 1 and about 10, about 5, greater than about 5, and/or the like. Intervals can be uniform in size and/or magnitude, such as each corresponding to a same amount. In the alternative, intervals can vary in size and/or magnitude, such as some with larger amounts and some with smaller amounts.

Threshold temperature broadly refers to any suitable value, such as a rated operating temperature of a diode, a maximum allowable junction temperature, and/or the like.

Reaching broadly refers to touching, attaining, encompassing, and/or the like. Reaching may include equaling a value, exceeding a value by an incremental amount and/or the like. The incremental amount may include any suitable value, such as by at least about 0.1 degrees Celsius, at least about 1 degree Celsius, at least about 2 degrees Celsius, at least about 5 degrees Celsius, at least about 10 degrees Celsius, and/or the like.

According to one embodiment of the photovoltaic module, the one or more temperature indication devices may include a temperature sensitive material that visually changes color and/or visually changes shape upon exposure to a threshold temperature or threshold temperature ranges.

Exposing to broadly refers to touching, reaching, attaining, and/or the like.

Changes of color broadly refer to a substance and/or a material changing optical properties, such as going from light to dark, white to black, green to black, and/or the like. Color changes may include any suitable color, hue, and/or brightness. Desirably, color changes can be readily perceived and/or discerned with an unaided eye.

Changes of shape broadly refer to a substance and/or a material changing dimensions and/or form, such as increasing a length, a width, an area, a diameter, and/or the like. Desirably, shape changes can be readily perceived and/or discerned with an unaided eye. Without being bound by theory, changes in shape may occur by reaching a melting point of a material and flowing of at least a portion of the material into a different shape.

The temperature indication devices may include any suitable material and/or substance, Such as a thermotropic liquid crystalline polymer, and/or the like.

According to one embodiment of the photovoltaic module, the one or more temperature indication devices may include a temperature indication label, a temperature sensitive paint, a temperature melting material, a temperature softening material, a temperature activated cement, a temperature activated lacquer, a temperature activated crayon, and/or the like.

The temperature indicating devices may include any suitable indicating range, such as between about −100 degrees Celsius to about 1,000 degrees Celsius, between about 0 degrees Celsius to about 500 degrees Celsius, between about 25 degrees Celsius and about 300 degrees Celsius, about 175 degrees Celsius, about 150 degrees Celsius, and/or the like. According to one embodiment of the photovoltaic module, the one or more temperature indication devices may include an indicating range of about 25 degrees Celsius to about 300 degrees Celsius.

According to one embodiment of the photovoltaic module, the one or more solar cells may include Czochralski silicon, float zone silicon, monocrystalline silicon, near monocrystalline silicon, microcrystalline silicon, metallurgical grade silicon, multicrystalline silicon, geometric multicrystalline silicon, amorphous silicon, cast silicon, sheet silicon, ribbon silicon, cadmium sulfide, cadmium telluride, copper indium selenide, copper indium gallium selenide, germanium, gallium arsenide, organic materials, polymer materials, and/or the like.

According to one embodiment, the invention may include an array of the photovoltaic modules of embodiments with any of features and/or functions disclosed within this specification.

According to one embodiment, the invention may include a method of fabricating a photovoltaic module. The method may include the step of providing one or more solar cells, and the step of electrically connecting one or more electrical circuits to the one or more solar cells. The method may include the step of contacting at least a portion of the one or more electrical circuits with one or more temperature indication devices, and the step of encapsulating the one or more solar cells, at least a portion of the one or more electrical circuits, and the one or more temperature indication devices between a transparent front sheet and a back sheet.

Fabricating broadly refers to constructing, making, assembling, and/or the like.

The step of encapsulating and/or laminating may include use of vacuum, compressive force, heat, and/or the like. Proper lamination can include structures without bubbles and/or wrinkles in the temperature indication device. Lamination of non-reversible temperature indication devices can avoid heating above the threshold temperature to provide proper operation of the non-reversible (permanent) temperature indication device during installation, commissioning, operation, and/or the like.

According to one embodiment of the method of fabricating, the one or more electrical circuits may include one or more diodes, and the one or more temperature indication devices may include active devices, passive devices, and/or the like.

### EXAMPLE

A mock photovoltaic module without working solar cells was fabricated as below. The mock photovoltaic module included blank solar cells, a printed circuit board with pre-mounted diodes, and temperature indication devices (temperature dots). These components were laminated between a transparent front sheet and a back sheet to form the mock photovoltaic module. The temperature dots successfully laminated into the mock photovoltaic module without bubbles and/or blistering. Embodiments with temperature indication devices to detect a temperate of other portions of and/or surroundings of the photovoltaic module are within the scope of this invention.

A reversible temperature indication device and a non-reversible temperature indication device were placed on the top side of the printed circuit board on top of and/or near the diodes. The reversible temperature indication devices can be useful for repeatedly detecting hot diodes in-situ while the photovoltaic module generates electrical power. The non-reversible temperature indication devices can be useful to permanently detect over-heated diodes.

The reversible temperature indication devices were reversible temperature dots filled with a liquid crystalline polymer, such as available from Omega Engineering Inc., Stamford Conn., U.S.A. The reversible temperature dots had a threshold temperature of 93.3 degrees Celsius (200 degrees Fahrenheit). The reversible temperature dots were green below 93.3 degrees Celsius and changed to black above about 93.3 degrees Celsius. Upon cooling to below the threshold temperature, the reversible temperature dots changed back to green.

The non-reversible temperature indication devices were non-reversible temperature dots, such as available from Omega Engineering Inc. and/or Tempil, an ITW Company, South Plainfield, N.J., U.S.A. The non-reversible temperature dots had a threshold temperature of 104.4 degrees Celsius (220 degrees Fahrenheit). The non-reversible temperature dots would change color upon reaching a threshold temperature (heating). The non-reversible temperature dots would not change back upon cooling below the threshold temperature. The non-reversible temperature dots did not undergo a color change during testing.

The front side and backside of the printed circuit board were measured by placing a K-type thermo-couple onto the front and backside of the printed circuit board. The diode was then heated by gradually ramping up the current flow from 2 amps at an interval of 1 amp. The thermocouple was connected to a Fluke data acquisition and logging device from Fluke Corporation, Everett, Wash., U.S.A.

The reversible temperature indication devices activated while heating the diodes. The thermocouple readings were 140 degrees Celsius when the reversible temperature indication devices changed from green to black (93.3 degrees Celsius). The temperature offset of the diodes to the temperature indication devices was due to a delay from the printed circuit board (insulation effect from the printed circuit board material). The temperature rating of the diodes (150 degrees Celsius) was not exceeded. The non-reversible temperature indication devices continued to indicate a temperature below 104.4 degrees Celsius.

The color change of the reversible temperature indication devices was easily observed from a front portion of the photovoltaic module through the transparent front sheet.

As used herein the terms “has”, “having”, “comprising” “with”, “containing”, and “including” are open and inclusive expressions. Alternately, the term “consisting” is a closed and exclusive expression. Should any ambiguity exist in construing any term in the claims or the specification, the intent of the drafter is toward open and inclusive expressions.

As used herein the term “and/or the like” provides support for any and all individual and combinations of items and/or members in a list, as well as support for equivalents of individual and combinations of items and/or members.

Regarding an order, number, sequence, and/or limit of repetition for steps in a method or process, the drafter intends no implied order, number, sequence and/or limit of repetition for the steps to the scope of the invention, unless explicitly provided.

Regarding ranges, ranges are to be construed as including all points between upper values and lower values, such as to provide support for all possible ranges contained between the upper values and the lower values including ranges with no upper bound and/or lower bound.

It will be apparent to those skilled in the art that various modifications and variations can be made in the disclosed structures and methods without departing from the scope or spirit of the invention. Particularly, descriptions of any one embodiment can be freely combined with descriptions of other embodiments to result in combinations and/or variations of two or more elements and/or limitations. Other embodiments of the invention will be apparent to those skilled in the art from consideration of the specification and practice of the invention disclosed herein. It is intended that the specification and examples be considered exemplary only, with a true scope and spirit of the invention being indicated by the following claims.

What is claimed is:

1. A method of installing, commissioning, operating, or maintaining a photovoltaic array, the method comprising:
providing one or more photovoltaic modules;
wherein the one or more photovoltaic modules comprise one or more solar cells, one or more diodes electrically connected to the one or more solar cells, and one or more temperature indication devices in communication with at least a portion of the one or more diodes and within at least a portion of the one or more photovoltaic modules; and
detecting a failure of the one or more diodes with the one or more temperature indication devices.

2. The method of claim 1, wherein:
the one or more diodes comprise bypass diodes, blocking diodes, or combinations thereof; and
the detecting comprises monitoring a passive device, an active device, or combinations thereof within the one or more photovoltaic modules or an array to assure proper installation, commissioning, operation, maintenance, reliability, safety, or combinations thereof.

3. The method of claim 1, further comprising:
correcting or repairing one or more of the one or more photovoltaic modules upon detecting a failure of the one or more diodes; or
replacing one or more of the one or more photovoltaic modules upon detecting a failure of the one or more diodes.

4. The method of claim 3, wherein the failure of the one or more diodes occurs due to reverse current flow, improper electrical connection, cracked solar cells, mismatched solar cells, shading of one or more solar cells, improper fusing within the photovoltaic module, improper grounding of the photovoltaic module, improper fusing outside the photovoltaic module, or combinations thereof.

5. The method of claim 1, wherein a technician or an installer performs a check of an array of the photovoltaic modules by visually inspecting the one or more temperature indication devices while traversing at least a portion of the array during or after installation.

6. The method of claim 5, wherein visually checking comprises easily observing a front portion of the photovoltaic module without physically opening a part of a photovoltaic module.

7. The method of claim 1, wherein the detecting a failure of the one or more diodes comprises monitoring an approach to a temperature rating of the one or more diodes, or monitoring a rise to or above a temperature rating of the one or more diodes.

8. The method of claim 7, wherein the temperature rating of the one or more diodes comprise a range of about 125 degrees Celsius to about 300 degrees Celsius.

9. The method of claim 1, further comprising:
mounting one or more photovoltaic modules to a support structure; and
electrically connecting the one or more photovoltaic modules.

10. A photovoltaic module for converting light into electricity, the module comprising:
one or more solar cells;
a transparent front sheet disposed over the one or more solar cells;
a back sheet opposite the transparent front sheet;
one or more electrical circuits connected to at least a portion of the one or more solar cells and comprising one or more diodes; and
one or more temperature indication devices in communication with at least a portion of the one or more diodes, and the one or more temperature indication devices disposed between the transparent front sheet and the back sheet.

11. The module of claim 10, further comprising one or more electrically conducting boards disposed between the transparent front sheet and the back sheet, and at least a portion of the one or more electrical circuits mounted to the one or more electrically conducting boards.

12. The module of claim 10, wherein:
the one or more diodes mount to one or more electrically conducting boards laminated between the transparent front sheet and the back sheet with the one or more diodes facing the one or more solar cells; and
the one or more temperature indication devices mount to the circuit board on a same side or an opposite side as the one or more diodes.

13. The module of claim 10, wherein the one or more temperature indication devices provide visual indication related to a temperature of at least a portion of the one or more electrical circuits.

14. The module of claim 13, wherein the one or more diodes comprise bypass diodes, blocking diodes, or combinations thereof.

15. The module of claim 14, wherein the one or more diodes comprise surface mount technology Schottky diodes integrally laminated into a portion of the photovoltaic module.

16. The module of claim 10, wherein the one or more temperature indication devices comprise reversible temperature indication devices, non-reversible temperature indication devices, active temperature indication devices, passive temperature indication devices, or combinations thereof.

17. The module of claim 10, wherein the one or more temperature indication devices comprise a scale to illustrate a temperature, or a color change to indicate a certain threshold temperature has been reached.

18. The module of claim 10, wherein the one or more temperature indication devices comprise a temperature sensitive material that visually changes color or visually changes shape upon exposure to a threshold temperature or threshold temperature ranges.

19. The module of claim 18, wherein the one or more temperature indication devices comprise a thermotropic liquid crystalline polymer.

20. The module of claim 18, wherein the one or more temperature indication devices comprise a temperature indication label, a temperature sensitive paint, a temperature melting material, a temperature softening material, a temperature activated cement, a temperature activated lacquer, a temperature activated crayon, or combinations thereof.

21. The module of claim 10, wherein the one or more temperature indication devices comprise an indicating range of about 125 degrees Celsius to about 300 degrees Celsius.

22. The module of claim 10, wherein the one or more solar cells comprise Czochralski silicon, float zone silicon, monocrystalline silicon, near monocrystalline silicon, microcrystalline silicon, multicrystalline silicon, geometric multicrystalline silicon, amorphous silicon, cast silicon, sheet silicon, ribbon silicon, cadmium sulfide, cadmium telluride, copper indium selenide, copper indium gallium selenide, germanium, gallium arsenide, organic materials, polymer materials, or combinations thereof.

23. An array of the modules of claim 10.

24. A method of fabricating a photovoltaic module, the method comprising:
providing one or more solar cells;
electrically connecting one or more electrical circuits to the one or more solar cells;
contacting at least a portion of the one or more electrical circuits with one or more temperature indication devices; and
encapsulating the one or more solar cells, at least a portion of the one or more electrical circuits, and the one or more temperature indication devices between a transparent front sheet and a back sheet.

25. The method of claim 24, wherein:
the one or more electrical circuits comprise one or more diodes; and
the one or more temperature indication devices comprise active devices, passive devices, or combinations thereof.
